(19) United States
(12) Patent Application Publication
(10) Pub. No.: US 2008/0158845 A1
(43) Pub. Date: Jul. 3, 2008

(54) SLIDE ASSEMBLY WITH FIXING DEVICE

(75) Inventors: ZHAO-GUO WEN, Shenzhen (CN); LI-HUI GAO, Shenzhen (CN); JIE LI, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (TW); HON HAI PRECISION INDUSTRY CO., LTD., Tu-Cheng (TW)

(21) Appl. No.: 11/768,926

(22) Filed: Jun. 27, 2007

(30) Foreign Application Priority Data
Dec. 29, 2006 (CN) 200620145395.5

(51) Int. Cl. H05K 5/02

(52) U.S. Cl. 361/809; 312/334.44

(57) ABSTRACT

A slide assembly (20) is attached to a side wall (11) of an electronic device. The side wall has a retaining member (113). The slide assembly includes a first slide (30), and a second slide (50) telescopically attached to the first slide. An engaging tab (33) is formed on the first slide for inserting in the retaining member in a lengthways direction to thereby secure the first slide to the side wall. A flexible fixing portion (41) is fixed on the first slide. The fixing portion blocks the retaining member in the lengthways direction for preventing engaging tab moving away from the retaining member. The fixing portion is reboundably moved away from the first slide in a lateral direction so as to release the retaining member from the engaging tab.

### BACKGROUND OF THE INVENTION

1. Field of the Invention

The present invention relates to a slide assembly with a fixing device, particularly to a slide assembly fixed to an electronic device.

2. Description of Related Art

A typical drawer will often have two slides securing the drawer to the cabinet or enclosure, and the slides attached to the outside of the drawer.

A conventional drawer slide member has a vertical web having guide apertures with angled sides leading to a slot adapted to receive support tabs projecting from an undermount bracket. The undermount bracket, or shelf mount bracket, is longitudinally restricted from motion, and the support tabs are thereby locked in the slots, by lock tabs located on a flexing finger within the undermount bracket which are positioned in a lock tab aperture in the web of the slide member. This slide member has a complex structure, and may have a high manufacturing cost, and is also difficult to operate.

What is needed, therefore, is a retaining mechanism having a simple structure for fixing a slide to an electronic device, and the slide can be easily attached to the electronic device.

### SUMMARY OF THE INVENTION

A slide assembly is attached to a side wall of an electronic device. The side wall has a retaining member. The slide assembly includes a first slide, and a second slide telescopically attached to the first slide. An engaging tab is formed on the first slide for inserting in the retaining member in a lengthways direction to thereby secure the first slide to the side wall. A flexible fixing portion is fixed on the first slide. The fixing portion blocks the retaining member in the lengthways direction for preventing engaging tab moving away from the retaining member. The fixing portion is reboundably moved away from the first slide in a lateral direction so as to release the retaining member from the engaging tab.

Other advantages and novel features of the present invention will become more apparent from the following detailed description of a preferred embodiment when taken in conjunction with the accompanying drawings, in which:

### BRIEF DESCRIPTION OF THE DRAWINGS

FIG. 1 is a partially exploded, isometric view of a slide assembly and an electronic device according to a preferred embodiment of the present invention, the slide assembly comprising an outer slide, a resilient member, and an inner slide;

FIG. 2 is similar to FIG. 1, but the resilient member is attached to the inner slide;

FIG. 3 is an isometric, assembled view of FIG. 1; and

FIG. 4 is a partial, sectional view of FIG. 3.

### DETAILED DESCRIPTION OF THE INVENTION

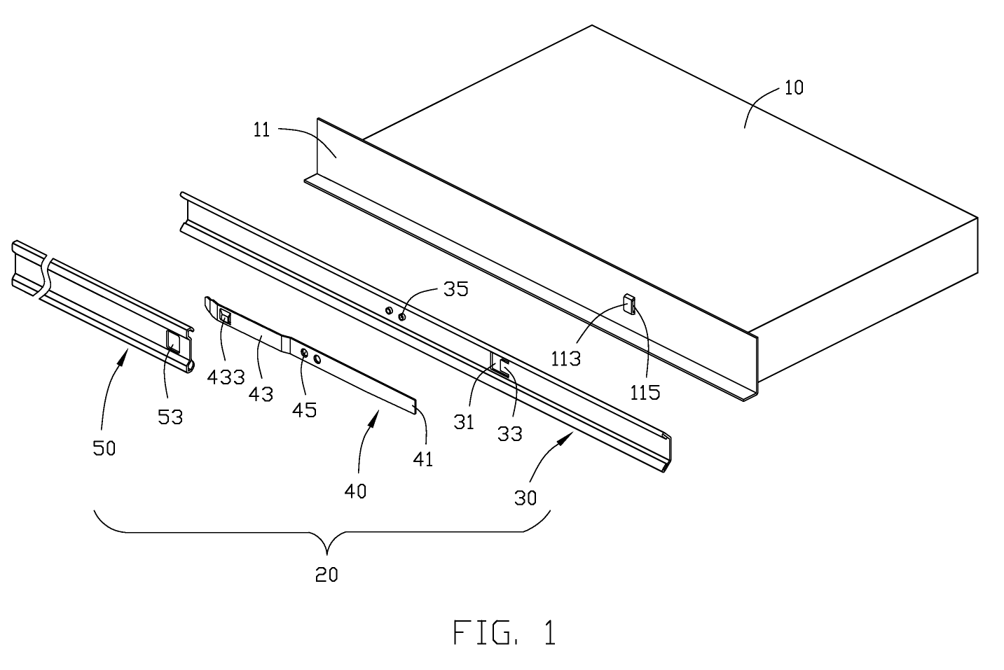

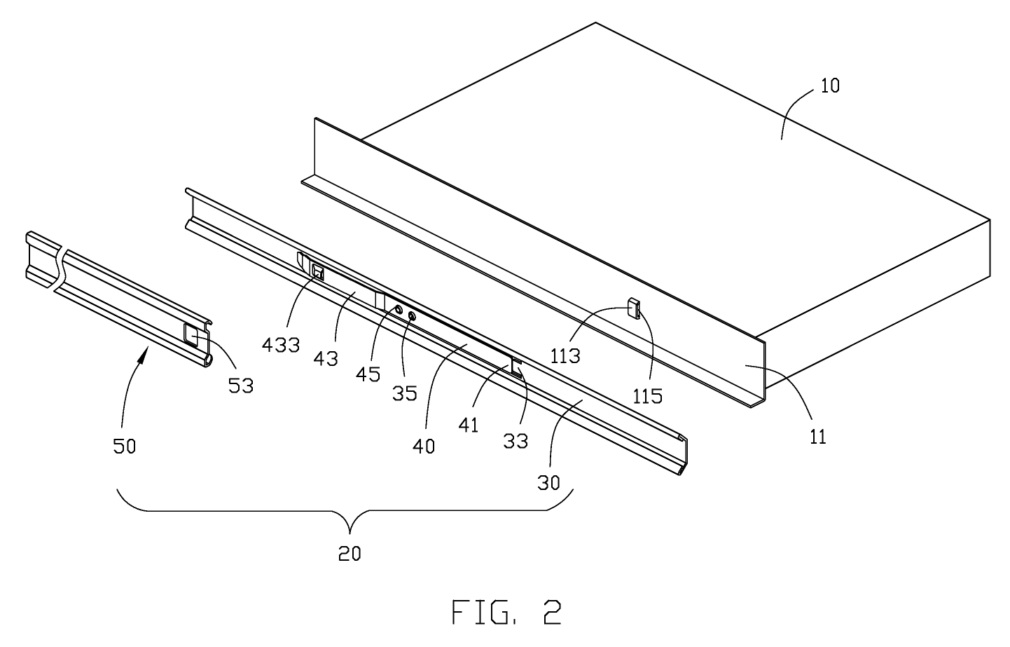

Referring to FIG. 1 and FIG. 2, a slide assembly 20 includes an inner slide 30, a resilient member 40, and an outer slide 50. The slide assembly 20 can be used to slidably attach an electronic device 10 to a cabinet (not shown). The electronic device 10 has a side wall 11. An arcuate bridge 113 is formed on the side wall 11 with a slot 115 defined therebetween.

The inner slide 30 has an entry opening 31 corresponding to the bridge 113. A tongue 33 serves as a holding tab which extends from one side of the entry opening 31. A pair of rivets 35 protrudes from an inner side of the inner slide 30.

The resilient member 40 has a fixing end 41 serving as a fixing portion at one end thereof, and an engaging protrusion 433 formed on a restricting portion 43 at the other end thereof. A pair of rivet holes 45 is defined at a middle portion of the resilient member 40 corresponding to the rivets 35.

The outer slide 50 has an engaging opening 53 for receiving the engaging protrusion 433 at one end thereof. The outer slide 50 can be fixed to the cabinet.

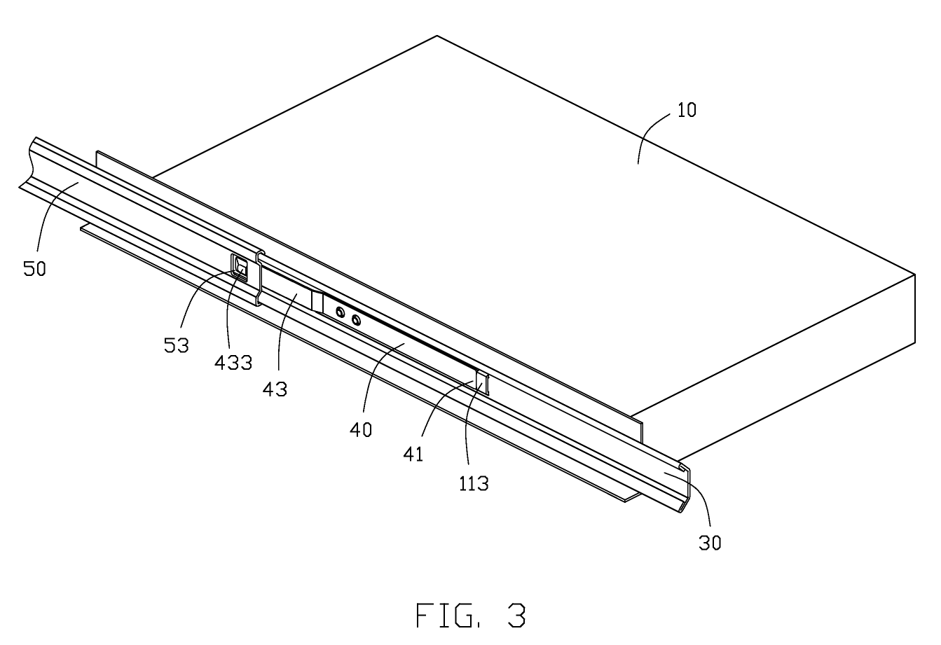

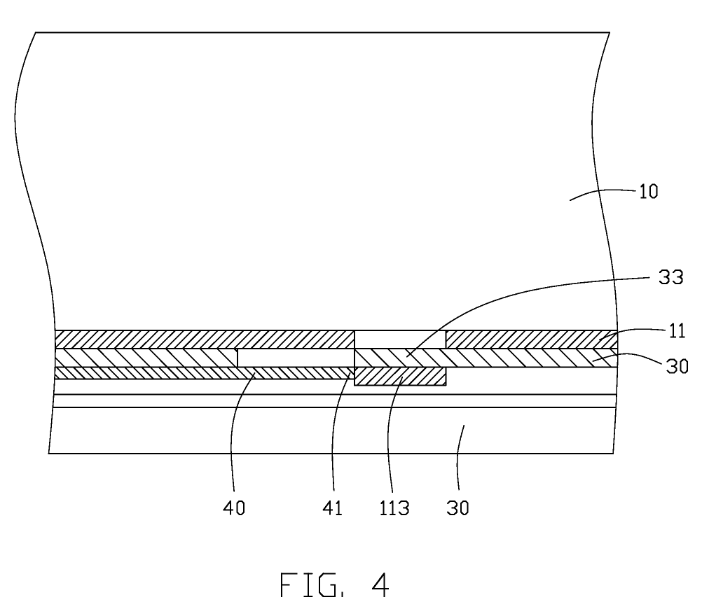

Referring also to FIG. 3 and FIG. 4, when assembling the slide assembly 20, the resilient member 40 is riveted to the inner slide 30 via the rivets 35 received in the corresponding rivet holes 45, and the inner slide 30 is telescopically mounted to the outer slide 50. Then the slide assembly 20 is fixed to the electronic device 10 in the following manner. The bridge 113 of the electronic device 10 is aligned with, and received in, the entry opening 31 of the slide assembly 20, thereby urging the fixing end 41 of the resilient member 40 to bend in a lateral direction away from the inner slide 30. The slide assembly 20 is moved along a lengthways direction so as to insert the tongue 33 into the slot 115 of the bridge 113. When the tongue 33 is totally inserted into the bridge 113, the fixing end 41 of the resilient member 40 is moved away and released from the bridge 113, the fixing end 41 rebounds to an original position, and a distal end of the fixing end 41 abuts against the bridge 113 to prevent the bridge 113 from moving out. Thus, the slide assembly 20 is fixed to the electronic device 10. When extending the slide assembly 20 which slides the electronic device 10 out from the cabinet, to an extended position, the outer slide 50 can be engaged with the resilient member 40 via the engaging protrusion 433 received in the engaging opening 53 for preventing the inner slide 30 from moving back, whereby retaining the electronic device 10 and the inner slide 30 in the extended position. When pushing the electronic device 10 back into the cabinet, the engaging protrusion 433 can be pressed in to disengage from the engaging opening 53 such that the inner slide 30 can be slid inward relative to the outer slide 50.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A slide assembly attached to a side wall of an electronic device, the side wall having a retaining member, the slide assembly comprising:
a first slide, an engaging tab formed on the first slide for inserting in the retaining member in a lengthways direction to thereby secure the first slide to the side wall, a flexible fixing portion fixed on the first slide, the fixing portion blocking the retaining member in the lengthways direction for preventing the engaging tab moving away from the retaining member, wherein the fixing portion is reboundably moved away from the first slide in a lateral direction so as to release the retaining member from the engaging tab; and
a second slide telescopically attached to the first slide.

2. The slide assembly as described in claim 1, wherein the retaining member is an arcuate bridge with a slot defined therein, the engaging tab being inserted in the slot.

3. The slide assembly as described in claim 2, wherein an entry opening is defined through the first slide, and the engaging tab extends from an inner side of the entry opening, the bridge extending through the opening and abutting against the fixing portion in the lengthways direction.

4. The slide assembly as described in claim 1, wherein a resilient member is riveted to the first slide, and the fixing portion is formed on a free end of the resilient member.

5. The slide assembly as described in claim 4, wherein the resilient member further comprises a resilient restricting portion opposing the fixing portion, and an engaging protrusion is formed on the restricting portion for engaging with an engaging opening defined in the second slide.

6. The slide assembly as described in claim 3, wherein the fixing portion extends to cover one portion of the opening such that when fixing the slide assembly to the side wall, the fixing portion is urged to move away from the first slide to allow the bridge to enter in the opening and rebounds to abut against the bridge after the fixing portion passing over the bridge.

7. A slide assembly attaching to a side wall of an electronic device, the side wall having a retaining member, the slide assembly comprising:
a first slide, an engaging tab formed on the first slide corresponding to the retaining member;
a resilient member attached to an inner side of the first slide away from the side wall, the resilient member comprising a fixing portion; and
a second slide telescopically attached to the inner side of the first slide, wherein the retaining member traverses the first slide to urge the fixing portion to resiliently move away from the inner side of the first slide, such that the retaining member is capable of engaging with the engaging tab, and the retaining member is blocked by a distal end of the fixing portion from moving out, when the fixing portion rebounds back to an original position as the fixing portion passes over the retaining member and the retaining member totally engages with the engaging tab.

8. The slide assembly as described in claim 7, wherein the retaining member is an arcuate bridge with a slot defined therein, the engaging tab being inserted in the slot.

9. The slide assembly as described in claim 8, wherein an entry opening is defined through the first slide, and the engaging tab extends from an inner side of the entry opening, the bridge extending through the opening and abutting against the fixing portion in the lengthways direction.

10. The slide assembly as described in claim 7, wherein the resilient member is riveted to the first slide, and the fixing portion is formed on a free end of the resilient member.

11. The slide assembly as described in claim 10, wherein the resilient member further comprises a resilient restricting portion opposing the fixing portion, and an engaging protrusion is formed on the restricting portion for engaging with an engaging opening defined in the second slide.

12. The slide assembly as described in claim 7, wherein the fixing portion is reboundably moved away from the first slide in a lateral direction so as to release the retaining member from the engaging tab.

13. A slide assembly configured to slidably attach an electronic device into a cabinet, the electronic device comprising a side wall having a bridge with a slot defined therein, the slide assembly comprising:
a first slide configured to be attached to the side wall, the first slide comprising an opening configured for extending through of the bridge, and an engaging tab extending from the first slide into one portion of the opening configured to be inserted into the slot of the bridge in a lengthways direction when the bridge enters in the opening;
a resilient plate fixed to one side of the first slide, the resilient member comprising a fixing portion extending to cover the other portion of the opening, the plate being deformable such that the fixing portion is moveable away from the one side of the first slide to allow the bridge to enter in the opening and reboundable to abut against the bridge in the lengthways direction after the fixing portion passing over the bridge in the lengthways direction to prevent the engaging tab from sliding out of the slot; and
a second slide configured to be fixed to the cabinet, the second slide telescopically attached to the first slide.

14. The slide assembly as described in claim 13, wherein the resilient plate further comprises a restricting portion opposing the fixing portion, a locking structure being formed on the restricting portion configured to lock with the second slide to thereby hold the first slide relative to the second slide, a space being formed between the restricting portion and the one side of the first slide in a lateral direction such that the restricting portion is pressable toward the one side of the first slide to disengage the locking structure from the second slide, thereby allowing the first slide to slide relative to the second slide in the lengthways direction.

15. The slide assembly as described in claim 14, wherein the resilient plate is fixed to the first slide via a portion between the fixing portion and the restricting portion riveted to the first slide.
